(19) United States
(12) Patent Application Publication
(10) Pub. No.: US 2010/0156531 A1
(43) Pub. Date: Jun. 24, 2010

(54) POWER AMPLIFIER, INTEGRATED CIRCUIT, AND COMMUNICATION APPARATUS

(76) Inventor: Michitoshi Hirata, Osaka (JP)

Correspondence Address: BIRCH STEWART KOLASCH & BIRCH, PO BOX 747, FALLS CHURCH, VA, 22040-0747, US

(21) Appl. No.: 12/542,009

(22) Filed: Aug. 17, 2009

(30) Foreign Application Priority Data
Dec. 22, 2008 (JP) 2008-326341

(51) Int. Cl. H03F 3/04

(52) U.S. Cl. 330/250

(57) ABSTRACT

A power amplifier of the present invention includes (i) a bipolar transistor for amplifying a signal supplied via a base terminal, so as to obtain an amplified signal, and outputting the amplified signal via a collector terminal and (ii) an inductor between an emitter terminal of the bipolar transistor and a ground. An inductance between the emitter terminal and the ground is larger than a parasitic inductance between the emitter terminal and the ground between which the inductor is not provided. This allows the bipolar transistor to increase an output power without increasing an emitter area. As a result, the present invention makes it possible to provide a highly efficient high-power power amplifier.

This Nonprovisional application claims priority under 35 U.S.C. §119(a) on Patent Application No. 2008-326341 filed in Japan on Dec. 22, 2008, the entire contents of which are hereby incorporated by reference.

### TECHNICAL FIELD

The present invention relates (i) to a power amplifier which is low in distortion, high in output power, and high in efficiency, and (ii) to a communication apparatus including the power amplifier.

### BACKGROUND ART

In general, portable phones and wireless communication adopt QPSK (Quadrature Phase Shift Keying), QAM (Quadrature Amplitude Modulation), etc. as digital modulation methods. According to the digital modulation methods, information is embedded in both amplitude and a phase of a signal. Accordingly, it is necessary to faithfully amplify a waveform of a signal. For this reason, a power amplifier is required to operate with low distortion.

As for broadband communication systems that enable long-distance high-speed transmission, it is possible to exemplify WiMAX, LTE, etc. Power amplifiers used in these broadband communication systems are required to be high in output power as compared to those used in a conventional WLAN, so that the power amplifiers can allow the broadband communication systems to perform the long-distance high-speed transmission. In addition, a power amplifier used in a mobile terminal such as a portable phone is further required to operate with high efficiency.

FIG. 14 is a view illustrating a power amplifier 1000 utilizing a single bipolar transistor which is commonly used conventionally. The power amplifier 1000 includes an input terminal 1001, a bipolar transistor 1002, an output terminal 1003, a voltage supply terminal 1004, and matching circuits 1005 and 1006. A high-frequency signal is supplied, via the input terminal 1001 and the matching circuit 1005, to a base terminal of the bipolar transistor 1002 whose emitter terminal is grounded. The supplied high-frequency signal is amplified by the bipolar transistor 1002. The amplified high-frequency signal is supplied to the matching circuit 1006 and finally outputted via the output terminal 1003. A base bias voltage of the bipolar transistor 1002 is supplied via the voltage supply terminal 1004.

The matching circuit 1005 is a circuit for matching an impedance of the input terminal 1001 to that of the base terminal of the bipolar transistor 1002. The matching circuit 1006 is a circuit for matching an output load of the collector terminal of the bipolar transistor 1002 to a required gain and output power of the bipolar transistor 1002.

It is possible to adjust an output power of the power amplifier 1000 illustrated in FIG. 14, by changing both an emitter size of the bipolar transistor 1002 and a load impedance of the matching circuit 1006. For example, in order to increase the output power of the power amplifier 1000, it is possible to increase a current of the power amplifier 1000 by increasing an emitter size of the bipolar transistor 1002 and decreasing a load impedance of the matching circuit 1006.

In case where a power amplifier is mounted on a semiconductor substrate, a parasitic inductance is always caused in an earth electrode. Since the parasitic inductance reduces a gain, a smaller parasitic inductance is preferable. With regard to this, Patent Literature 1 (Japanese Unexamined Patent Application Publication, Tokukai, No. 2007-228094 A (Publication Date: Sep. 6, 2007)) discloses a power amplifier that has an arrangement in which a capacitor is provided between an emitter terminal of a transistor and a ground, and thereby suppresses a decrease in gain due to a parasitic inductance.

According to the arrangement disclosed in Patent Literature 1, however, an output power of the power amplifier cannot be increased since the purpose of the arrangement is to suppress an influence of the parasitic inductance. As for the conventional power amplifier 1000 illustrated in FIG. 14, an output power is increased by an arrangement in which the emitter size of the bipolar transistor 1002 is increased and the load impedance of the matching circuit 1006 is decreased. According to the arrangement, unfortunately, the higher the output power, the larger the power consumption. This makes it difficult to realize a highly efficient high-power power amplifier.

### Citation List

Patent Literature 1

Japanese Unexamined Patent Application Publication, Tokukai, No. 2007-228094 A (Publication Date: Sep. 6, 2007)

### SUMMARY OF INVENTION

The present invention was made to solve the problem. An object of the present invention is to provide a highly efficient high-power power amplifier.

In order to attain the object, a power amplifier according to the present invention is a power amplifier including a first bipolar transistor for amplifying a signal supplied thereto via a base terminal of the first bipolar transistor, so as to obtain an amplified signal, and outputting the amplified signal via a collector terminal of the first bipolar transistor, the power amplifier including: an additional inductance element between an emitter terminal of the first bipolar transistor and a ground, an inductance between the emitter terminal and the ground between which the additional inductance element is provided being larger than a parasitic inductance between the emitter terminal and the ground between which the additional inductance element is not provided.

According to the arrangement, the power amplifier is a grounded-emitter amplifier whose emitter is grounded. Providing the additional inductance element between the emitter terminal and the ground causes the larger inductance between the emitter terminal and the ground than the parasitic inductance between the emitter terminal and the ground between which the additional inductance element is not provided. The larger the inductance between the emitter terminal and the ground, the higher the output power of the grounded-emitter amplifier. In order to increase an output power of the power amplifier of the present invention, accordingly, it is not necessary to increase an emitter area. This makes it possible to suppress an increase in power consumption. This makes it possible to provide a highly efficient high-power power amplifier.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a view illustrating a circuit of a power amplifier of a first embodiment of the present invention.

FIG. 2 is a graph showing relations between output powers and gains, for the power amplifier of the first embodiment of the present invention and a conventional power amplifier.

FIG. 3 is a graph showing relations between output powers and gain deviations, for the power amplifier of the first embodiment of the present invention and the conventional power amplifier.

FIG. 4 is a graph showing relations between output powers and efficiencies, for the power amplifier of the first embodiment of the present invention and the conventional power amplifier.

FIG. 5 is a graph showing relations between output powers and gains, for the power amplifier of the first embodiment of the present invention and the conventional power amplifier.

FIG. 6 is a graph showing relations between output powers and gain deviations, for the power amplifier of the first embodiment of the present invention and the conventional power amplifier.

FIG. 7 is a graph showing relations between output powers and efficiencies, for the power amplifier of the first embodiment of the present invention and the conventional power amplifier.

FIG. 8 is a graph showing relations between output powers and gain deviations, for the power amplifier of the first embodiment of the present invention and the conventional power amplifier.

FIG. 9 is a view illustrating a circuit of a power amplifier of a second embodiment of the present invention.

FIG. 10 is a view illustrating a circuit of a power amplifier of a third embodiment of the present invention.

FIG. 11 is a view illustrating a circuit of a power amplifier of a forth embodiment of the present invention.

FIG. 12 is a view illustrating a circuit of a power amplifier of a fifth embodiment of the present invention.

FIG. 13 is a view illustrating a circuit of a communication apparatus of a sixth embodiment of the present invention.

FIG. 14 is a view illustrating a circuit configuration of the conventional power amplifier.

### DESCRIPTION OF EMBODIMENTS

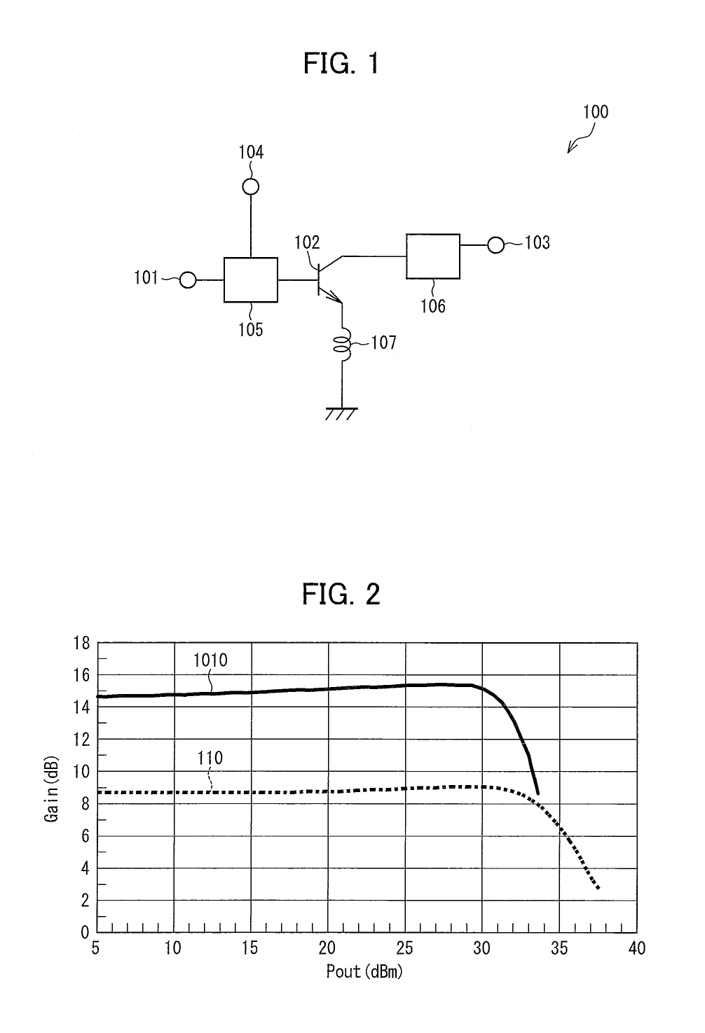

The following describes embodiments of the present invention, with reference to FIGS. 1 through 13.

### First Embodiment

The following describes a first embodiment of the present invention, with reference to FIGS. 1 through 7.

FIG. 1 illustrates a circuit of a power amplifier 100 of the present embodiment. The power amplifier 100 utilizes a single bipolar transistor. The power amplifier 100 includes an input terminal 101, a bipolar transistor 102, an output terminal 103, a voltage supply terminal 104, matching circuits 105 and 106, and an inductor 107 (additional inductance element 107). The input terminal 101, the bipolar transistor 102, the output terminal 103, the voltage supply terminal 104, and the matching circuits 105 and 106 are substantially the same as the following components of a conventional power amplifier 1000 illustrated in FIG. 14: an input terminal 1001, a bipolar transistor 1002, an output terminal 1003, a voltage supply terminal 1004, and matching circuits 1005 and 1006, respectively. The bipolar transistors 102 and 1002 are identical in emitter size. In summary, the power amplifier 100 illustrated in FIG. 1 includes the inductor 107, in addition to the components of the conventional power amplifier 1000 illustrated in FIG. 14.

In the power amplifier 100, a high-frequency signal is supplied, via the input terminal 101 and the matching circuit 105, to a base terminal of the bipolar transistor 102. The supplied high-frequency signal is amplified by the bipolar transistor 102. The amplified high-frequency signal is supplied to the matching circuit 106 via a collector terminal of the bipolar transistor 102. Finally, the amplified high-frequency signal is outputted via the output terminal 103. A base bias voltage of the bipolar transistor 102 is supplied via the voltage supply terminal 104.

The matching circuit 105 is a circuit for matching an impedance of the input terminal 101 to that of the base terminal of the bipolar transistor 102. The matching circuit 106 is a circuit for matching an output load of the collector terminal of the bipolar transistor 102 to required characteristics of the bipolar transistor 102.

The inductor 107 having a predetermined impedance is provided between an emitter terminal of the bipolar transistor 102 and a ground. The inductor 107 may be realized by the provision of a coil. Alternatively, the inductor 107 may be realized by the provision of a metal wire, a bonding wire, a spiral coil, or the like, as described later. Due to the provision of the inductor 107, an inductance between the emitter terminal of the bipolar transistor 102 and the ground is larger than a parasitic inductance caused therebetween in a case where the emitter terminal is directly grounded.

As shown above, the conventional power amplifier 1000 illustrated in FIG. 14 and the power amplifier 100 illustrated in FIG. 1 of the present embodiment are different only in whether the inductor 107 illustrated in FIG. 1 is provided or not. Except for this, the bipolar transistors 102 and 1002 are identical for example in emitter size etc. The matching circuits 106 and 1006 have substantially the same load impedance because the matching circuits 106 and 1006 are identical circuits. Therefore, the power amplifier 100 consumes the same amount of power as that consumed by the conventional power amplifier 1000.

In addition, an output power of the power amplifier 100 is higher than that of the power amplifier 1000 because the power amplifier 100 has a larger inductance between the emitter terminal of the bipolar transistor 102 and the ground than an inductance that the conventional power amplifier 1000 has between the emitter terminal of the bipolar transistor 1002 and the ground. In the present embodiment, an inductance of the inductor 107 is set to 50 pH. The following describes an output power of the power amplifier 100 concretely, based on the example where the inductance of the inductor 107 is 50 pH.

Output powers of the conventional power amplifier 1000 illustrated in FIG. 14 were compared with those of the power amplifier 100 of the present embodiment by means of simulation. FIG. 2 shows a result of the simulation. In FIG. 2, the vertical axis represents gains (Gain) while the horizontal axis represents output powers (Pout). In FIG. 2, the solid line 1010 represents a simulated result of the conventional power amplifier 1000 while the dashed line 110 represents a simulated result of the power amplifier 100 of the present embodiment.

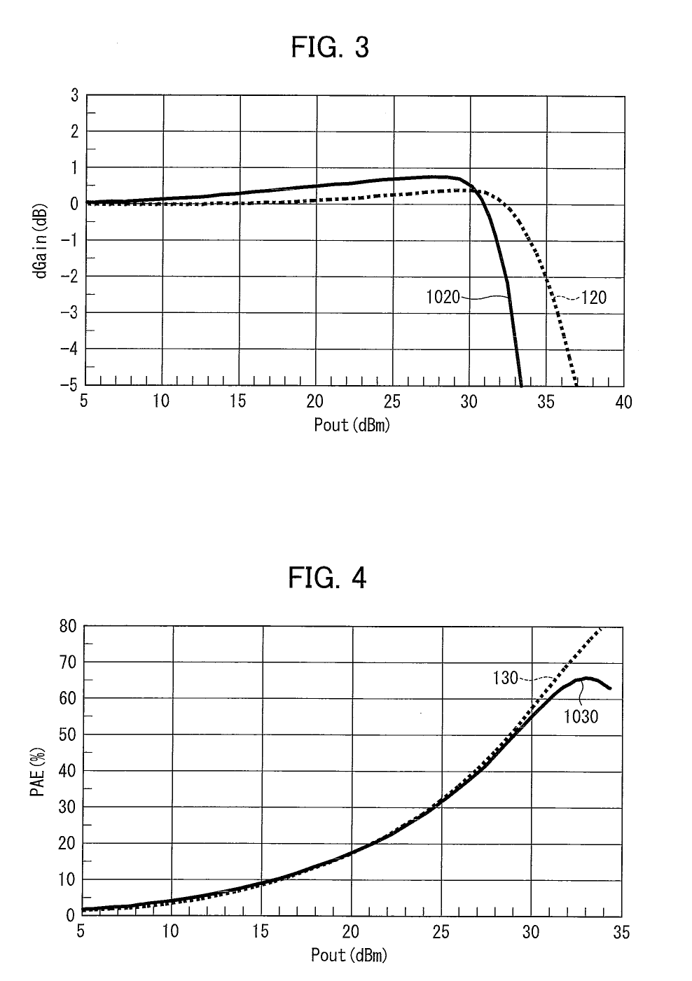

FIG. 2 shows that respective gains of the power amplifiers 100 and 1000 both drastically attenuated when respective output powers increased to certain levels. It is assumed that, as to each power amplifier, an output power corresponding to a gain attenuated by about 5 dB than that corresponding to an output power of 5 dBm is a saturated output power of the power amplifier. For a clear representation of each saturated output power, gain deviations were found on the basis of the gains shown in FIG. 2. The gain deviations are shown in FIG. 3.

In FIG. 3, the vertical axis represents gain deviations (dGain) while the horizontal axis represents output powers. The solid line 1020 represents gain deviations of the conventional power amplifier 1000 while the dashed line 120 represents gain deviations of the power amplifier 100 of the present embodiment. Since FIG. 3 shows the gain deviations, it is assumed that, as to each power amplifier, an output power corresponding to a value of −5 on the vertical axis is a saturated output power of the power amplifier.

FIG. 3 shows that the saturated output power indicated with the dashed line 120 was higher than that indicated with the solid line 1020. This demonstrates that the output power of the power amplifier 100 of the present embodiment is higher than that of the conventional power amplifier 1000. That is, the power amplifier 100 of the present embodiment reached a higher output power than that of the conventional power amplifier 100 for the reason that the power amplifier 100 had the inductor 107.

FIG. 4 shows efficiencies (PAE: Power Added Efficiencies) of each power amplifier, in accordance with the gain deviations shown in FIG. 3. In FIG. 4, the vertical axis represents efficiencies while the horizontal axis represents output powers. The solid line 1030 represents efficiencies of the conventional power amplifier 1000 illustrated in FIG. 14 while the dashed line 130 represents efficiencies of the power amplifier 100 of the present embodiment. FIG. 4 shows that the power amplifier 100 of the present embodiment was capable of an increase in output power (saturated output power), without suffering from a decrease in efficiency, as compared to the conventional power amplifier 1000.

The following compares a characteristic of the power amplifier 100 with that of the conventional power amplifier 1000, as to a case where a saturated output power of the power amplifier 100 of the present embodiment is adjusted so as to be substantially equal to that of the conventional power amplifier 1000. Specifically, the saturated output power of the power amplifier 100 was reduced so as to be substantially equal to that of the conventional power amplifier 1000 in such a manner that a load impedance of the matching circuit 106 illustrated in FIG. 1 was set larger than that of the matching circuit 1006 illustrated in FIG. 14. Also in this case, an inductance of the inductor 107 was set to 50 pH. The comparison result is shown in FIG. 5.

FIG. 5 shows relations between output powers and gains, for the power amplifier 100 of the present embodiment and the conventional power amplifier 1000. In FIG. 5, the vertical axis represents gains while the horizontal axis represents output powers. The solid line 1040 represents gains of the conventional power amplifier 1000 while the dashed line 140 represents gains of the power amplifier 100 of the present embodiment. As shown in FIG. 5, for both the power amplifiers 1000 and 100, the higher the output power, the lower the gain. In addition, FIG. 5 shows that an output power of the conventional power amplifier 1000 decreases at a greater rate as compared to that of the power amplifier 100 of the present embodiment.

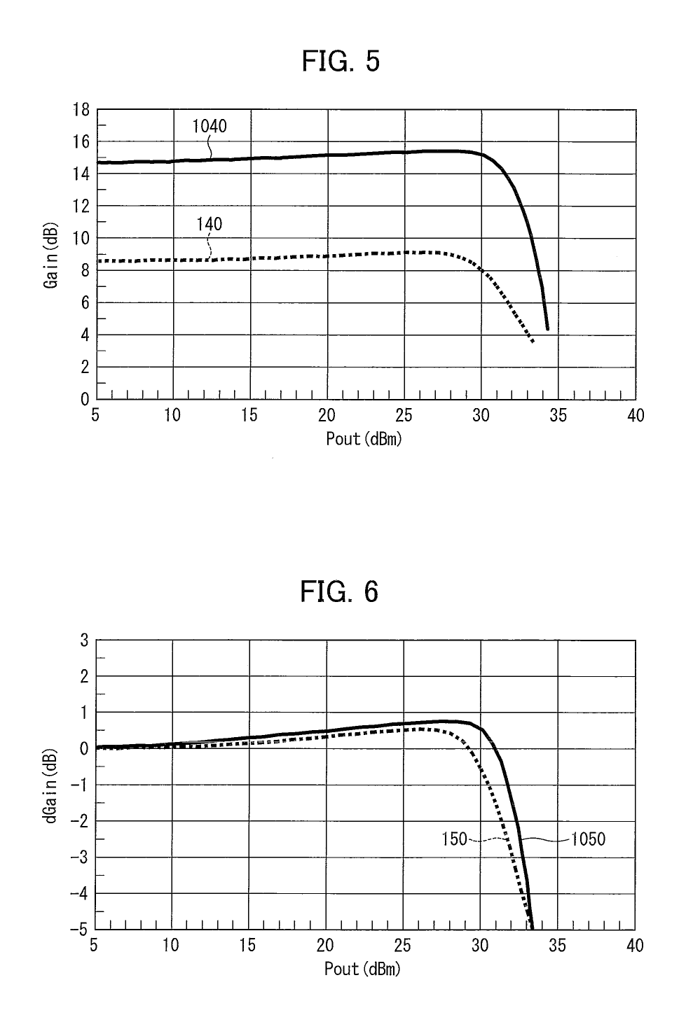

FIG. 6 shows relations between output powers and gain deviations, for the power amplifier 100 of the present embodiment and the conventional power amplifier 1000. In FIG. 6, the vertical axis represents gain deviations while the horizontal axis represents output powers. The solid line 1050 represents gain deviations of the conventional power amplifier 1000 while the dashed line 150 represents gain deviations of the power amplifier 100 of the present embodiment. It is assumed that, as to each power amplifier, an output power corresponding to a gain deviation of nearly −5 is a saturated output power of the power amplifier. FIG. 6 shows that a saturated output power of the power amplifier 100 of the present embodiment was reduced so as to be substantially equal to that of the conventional power amplifier 1000.

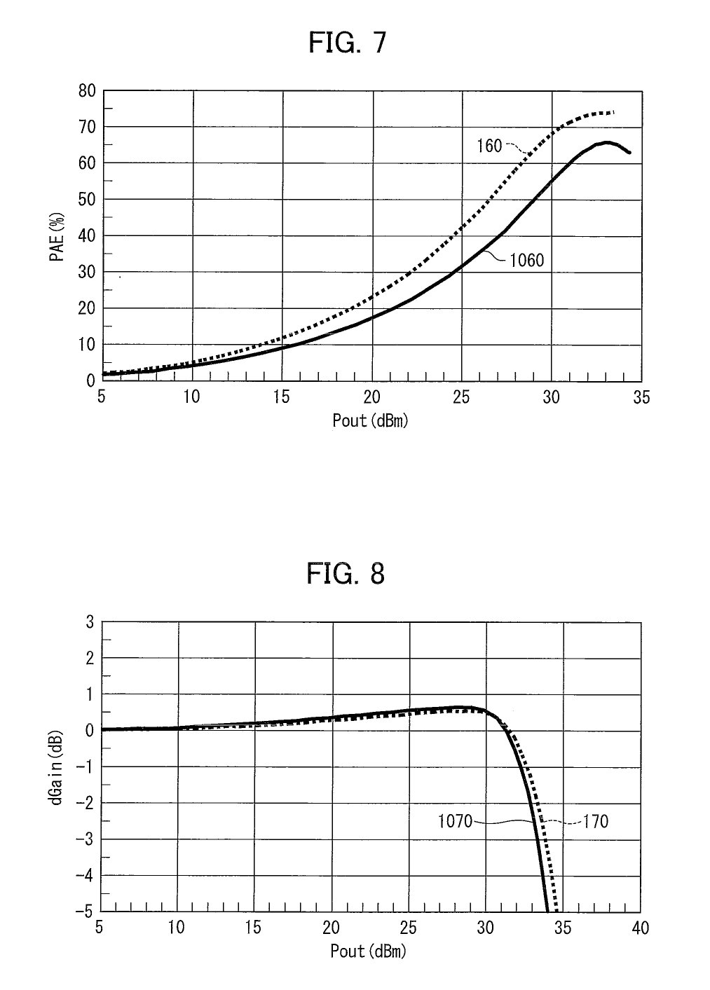

The following compares efficiencies of the power amplifier 100 of the present embodiment and those of the conventional power amplifier 1000, as to a case where the power amplifiers 100 and 1000 have substantially the same saturated output power. FIG. 7 shows relations between output powers and efficiencies, for the power amplifier 100 of the present embodiment and the conventional power amplifier 1000. In FIG. 7, the vertical axis represents efficiencies while the horizontal axis represents output powers. The solid line 1060 represents efficiencies of the conventional power amplifier 1000 while the dashed line 160 represents efficiencies of the power amplifier 100 of the present embodiment. As shown in FIG. 7, the power amplifier 100 of the present embodiment was improved in efficiency as compared to the conventional power amplifier 1000 in a case where the power amplifiers 100 and 1000 had substantially the same saturated output power.

This demonstrates that the power amplifier 100 of the present embodiment achieves a high output power and a high efficiency.

In a case where the emitter terminal is grounded, in the power amplifier 100 illustrated in FIG. 1, a parasitic inductance is caused between the emitter terminal of the bipolar transistor 102 and the ground. For this reason, an inductance of the inductor 107 is set larger than the parasitic inductance.

The parasitic inductance is caused due to a semiconductor process of the bipolar transistor. That is, the parasitic inductance is caused by lack of ideal connection between the emitter terminal and the ground. In order to obtain a desired effect from the power amplifier of the present embodiment, it is necessary to set the inductance of the inductor 107 larger than the parasitic inductance.

The parasitic inductance is mostly an inductance between the emitter terminal and the ground. In general, an emitter terminal of a power amplifier and a ground are connected via a VIA hole which is a through hole for grounding and is provided in a semiconductor substrate, or via a metal wire. In an actual product having a power amplifier, the power amplifier is mounted on a resin substrate in many cases. In such a case, another parasitic inductance is caused in a grounding wire of the resin substrate. The parasitic inductance varies depending on a type of the resin substrate, a type of the grounding wire, and an installation area of the power amplifier. All the parasitic inductances total a few picohenries in the case of a small total, or approximately 10 pH in the case of a large total.

A simulation was performed on the assumption that a parasitic inductance is large. Specifically, the parasitic inductance was assumed to be 10 pH, and accordingly, an inductance of the inductor 107 was set to 10 pH. FIG. 8 shows relations between output powers and gain deviations, as a result of the simulation. The vertical axis represents gain deviations while the horizontal axis represents output powers. The solid line 1070 represents gain deviations found in a case where the inductor 107 was not provided, but only a parasitic inductance was present while the dashed line 170 represents gain deviations found in a case where an inductance of 10 pH of the inductor 107 was added. FIG. 8 shows that adding the inductance of 10 pH of the inductor 107 produced an effect of increasing a saturated output power.

Therefore, it is preferable that an inductance of the inductor 107 is set larger than a sum of parasitic inductances. For this reason, as to the power amplifier of the present embodiment, an inductance of the inductor 107 is set to 10 pH. This makes it possible to provide a power amplifier with an increased output power and a sufficiently high efficiency.

The inductor 107 may be formed from a metal wire or a transmission line both formed on a semiconductor substrate. That is, a metal wire or a transmission line is formed longer than that of a general layout, thereby forming the inductor 107. The metal wire or transmission line can be freely designed in any shape. Therefore, it is possible to form the inductor 107 by utilizing a space between metal wires or transmission lines. This allows an effective use of a metal wire etc. on a semiconductor substrate.

In a case where a metal wire or a transmission line is formed as the inductor 107, a parasitic resistance is caused in the inductor 107. The parasitic resistance causes an effect of decreasing a gain of the bipolar transistor 102. This also decreases the saturated output power of the power amplifier 100. As described above, the larger the parasitic resistance of the inductor 107, the smaller the effect of increasing an output power of the power amplifier 100. Therefore, it is preferable that the parasitic resistance is as small as possible.

In other words, it is necessary to set an impedance Z_{L}(=|ΩL|) of the inductor 107 sufficiently larger than an impedance component Z_{R}(=R) which is a parasitic resistance of the inductor 107. Further, it is necessary to reduce an absolute value of the impedance component Z_{R}.

In the present embodiment, in view of this, it is possible to increase the saturated output power of the power amplifier 100 by (i) setting the impedance Z_{L} of the inductor 107 larger than the impedance component Z_{R} which is a parasitic resistance of the inductor 107, while (ii) reducing an absolute value of the impedance component Z_{R}.

### Second Embodiment

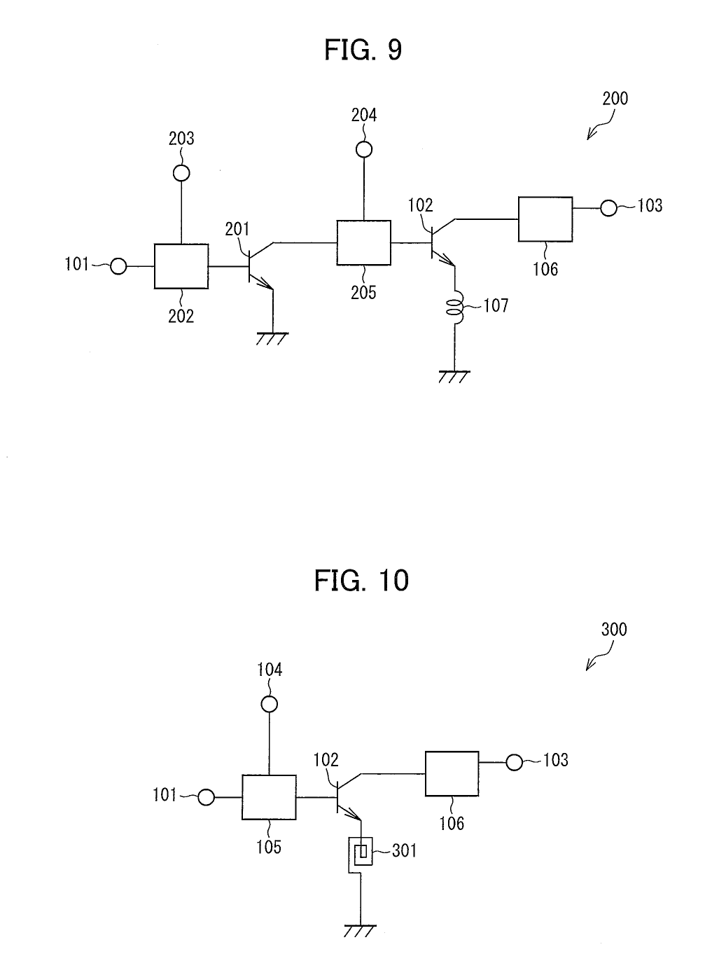

The following describes a second embodiment of the present invention, with reference to FIG. 9. Members which are the same as those of the first embodiment are given the same reference numerals, and descriptions for such members are omitted.

As shown in FIGS. 2 and 5, a gain of the power amplifier 100 of the present invention tends to decrease as compared to the conventional power amplifier 1000 in a case where the inductor 107 is connected to the emitter terminal of the bipolar transistor 102. In view of this, the present embodiment is arranged such that two bipolar transistors are provided in a power amplifier so that a decrease in gain is compensated.

FIG. 9 is a view illustrating a circuit configuration of a power amplifier 200 of the present embodiment. The power amplifier 200 is arranged similarly to the power amplifier 100 illustrated in FIG. 1, except that (i) a bipolar transistor 201, a matching circuit 202, and a voltage supply terminal 203 are further provided, and (ii) the voltage supply terminal 104 and the matching circuit 105 of the power amplifier 100 are replaced with a voltage supply terminal 204 and a matching circuit 205, respectively.

In the power amplifier 200, a high-frequency signal is supplied, via the input terminal 101 and the matching circuit 202, to a base terminal of the bipolar transistor 201. The supplied high-frequency signal is amplified by the bipolar transistor 201. An emitter terminal of the bipolar transistor 201 is grounded. The amplified high-frequency signal is supplied, via a collector terminal of the bipolar transistor 201 and the matching circuit 205, to the base terminal of the bipolar transistor 102.

Respective base bias voltages of the bipolar transistors 201 and 102 are supplied via the voltage supply terminals 203 and 204, respectively. The matching circuit 202 is a circuit for matching an impedance of the input terminal 101 to that of the base terminal of the bipolar transistor 201. The matching circuit 205 is a circuit for matching a load of the collector terminal of the bipolar transistor 201 to that of the base terminal of the bipolar transistor 102.

With the arrangement, the high-frequency signal supplied via the input terminal 101 is initially amplified by the bipolar transistor 201, and further amplified by the bipolar transistor 102. The high-frequency signal amplified by the bipolar transistor 102 is outputted via the collector terminal of the bipolar transistor 102, and supplied to the matching circuit 106.

The arrangement in which the bipolar transistor 201 is further provided in the upstream of the bipolar transistor 102 makes it possible to compensate a decrease in gain of the bipolar transistor 102 due to the provision of the inductor 107.

If a sufficient gain cannot be obtained from the power amplifier 200 illustrated in FIG. 9, a bipolar transistor can be further provided in the upstream of the bipolar transistor 201. In other words, a decrease in gain can be compensated by use of a power amplifier which includes three bipolar transistors.

In the present embodiment, an inductance of the inductor 107 is set to 50 pH, as is the case with the first embodiment.

### Third Embodiment

The following describes a third embodiment of the present invention, with reference to FIG. 10. Members which are the same as those of the first embodiment are given the same reference numerals, and descriptions for such members are omitted.

FIG. 10 illustrates a circuit of a power amplifier 300 of the present embodiment utilizing a single bipolar transistor. The power amplifier 300 is arranged similarly to the power amplifier 100 illustrated in FIG. 1, except that a spiral coil 301 is provided instead of the inductor 107. The use of the spiral coil 301 makes it possible to give an inductance element a large inductance.

As is described in the first embodiment, a long metal wire is necessary for a large inductance in a case where the inductance element is formed from a metal wire. This requires a large area of a semiconductor chip at mounting a power amplifier on a semiconductor substrate. This leads to a difficulty in the layout of a power amplifier.

According to the present embodiment, in contrast, the spiral coil 301 is used as an inductor. This realizes an effective use of an area for mounting a semiconductor chip, and further, a large inductance.

As a result, the power amplifier of the present embodiment can achieve a large saturated output power, with a simpler arrangement.

### Fourth Embodiment

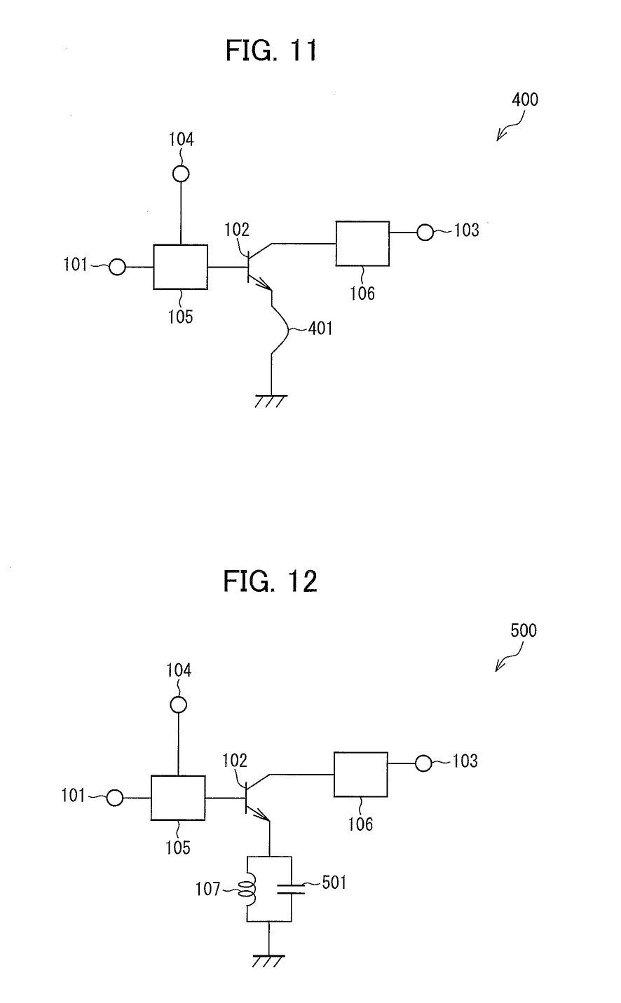

The following describes a fourth embodiment of the present invention, with reference to FIG. 11. Members which are the same as those of the first embodiment are given the same reference numerals, and descriptions for such members are omitted.

FIG. 11 illustrates a circuit of a power amplifier 400 of the present embodiment. The power amplifier 400 utilizes a single bipolar transistor. The power amplifier 400 is arranged as with the case with the power amplifier 100 illustrated in FIG. 1, except that a bonding wire 401 is provided instead of the inductor 107. That is, the bonding wire 401 is formed longer than that of a common connected state, thereby an inductor being realized. The bonding wire 401 has a smaller parasitic resistance than that of a metal wire or a spiral coil. Therefore, the bonding wire 401 makes it possible to further suppress a decrease in saturated output power of the power amplifier 400.

In other words, the power amplifier 400 of the present embodiment makes it possible to achieve a large saturated output power as compared to a power amplifier utilizing a metal wire or a spiral coil as an inductance element.

### Fifth Embodiment

The following describes a fifth embodiment of the present invention, with reference to FIG. 12. Members which are the same as those of the first embodiment are given the same reference numerals, and descriptions for such members are omitted.

FIG. 12 illustrates a circuit of a power amplifier 500 of the present embodiment. The power amplifier 500 utilizes a single bipolar transistor. The power amplifier 500 is arranged similarly to the power amplifier 100 illustrated in FIG. 1, except that a capacitor 501 is further provided. The capacitor 501 is connected, between the emitter terminal of the bipolar transistor 102 and the ground, in parallel with the inductor 107.

The parallel connection between the inductor 107 and the capacitor 501 produces a resonance effect. Depending on a capacitance of the capacitor 501 and an inductance of the inductor 107, an inductance between the emitter terminal and the ground can be decreased due to a resonance effect. In view of this, in the present embodiment, an inductance of the inductor 107 and a capacitance of the capacitor 501 are determined so that an inductance between the emitter terminal and the ground is increased due to a resonance effect. This makes it possible to cause a larger inductance component.

In other words, in a case where a large inductance is required, this allows the power amplifier 500 of the present embodiment to have an arrangement which makes it possible to easily obtain a large inductance, as compared to that of a power amplifier which uses only a metal wire, a spiral coil, or a bonding wire as an inductance element. This makes it possible to easily achieve a large saturated output power of the power amplifier.

### Sixth Embodiment

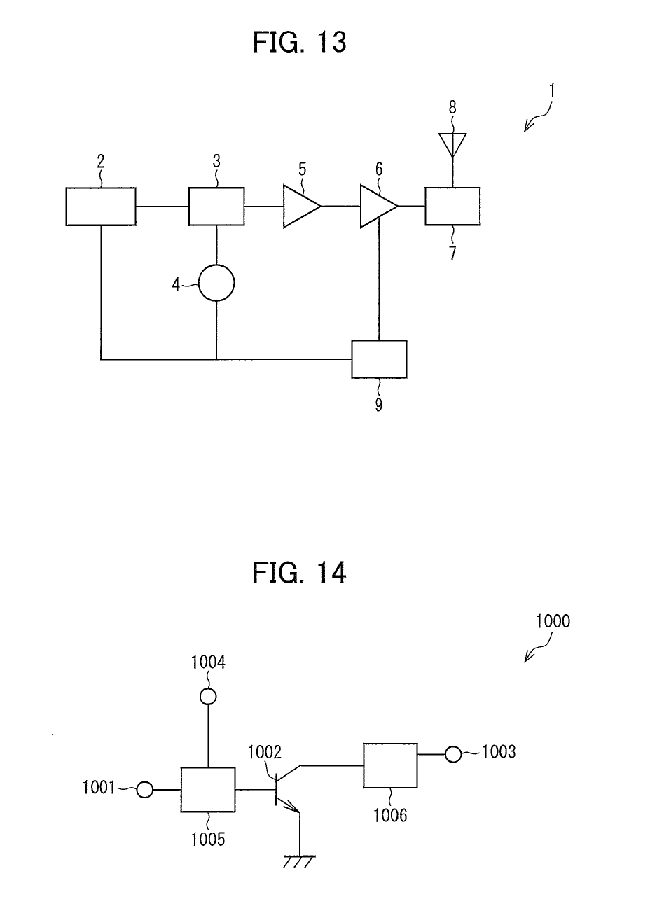

The following describes a sixth embodiment of the present invention, with reference to FIG. 13.

FIG. 13 is a block diagram illustrating a schematic arrangement of a communication apparatus 1 of the present embodiment. The communication apparatus 1 includes a signal processing circuit 2, a modulator 3, a local oscillator 4, a driver amplifier 5, a transmission power amplifier 6, a transmit-receive selector switch 7, an antenna 8, and a power supply 9.

A signal processed in the signal processing circuit 2 is supplied to the modulator 3. A carrier signal outputted from the local oscillator 4 is also supplied to the modulator 3. The modulator 3 modulates the carrier signal in accordance with the signal supplied from the signal processing circuit 2. The modulated signal is supplied to the driver amplifier 5 which amplifies the modulated signal. Then, the amplified signal is supplied to the transmission power amplifier 6 so as to be amplified. The modulated signal outputted from the transmission power amplifier 6 is transmitted from the antenna 8 via the transmit-receive selector switch 7. Power is supplied by the power supply 9 to the signal processing circuit 2, the local oscillator 4, and the transmission power amplifier 6.

The transmission power amplifier 6 includes any one of the power amplifiers 100, 200, 300, 400, and 500, which are described in the first through fifth embodiments. The communication apparatus 1 of the present embodiment achieves a high output power and a high efficiency.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

As described above, the power amplifier of the present invention is a power amplifier including a first bipolar transistor for amplifying a signal supplied thereto via a base terminal of the first bipolar transistor, so as to obtain an amplified signal, and outputting the amplified signal via a collector terminal of the first bipolar transistor, the power amplifier including: an additional inductance element between an emitter terminal of the first bipolar transistor and a ground, an inductance between the emitter terminal and the ground between which the additional inductance element is provided being larger than a parasitic inductance between the emitter terminal and the ground between which the additional inductance element is not provided. This makes it possible to provide a highly efficient high-power power amplifier.

The power amplifier of the present invention is preferably arranged such that the additional inductance element is formed from a metal wire.

Further, the power amplifier of the present invention is preferably arranged such that the additional inductance element is formed from a transmission line.

A shape of a metal wire or a transmission line can be freely changed for a layout. According to the arrangement, therefore, it is possible to realize the additional inductance element by utilizing a space between metal wires or transmission lines. This allows an effective use of a metal wire etc. on a semiconductor chip.

Further, the power amplifier of the present invention is preferably arranged such that the additional inductance element is formed from a spiral coil.

According to the arrangement, the spiral coil makes it possible to realize a large inductance with a small chip area. This makes it possible to easily increase an output power of the power amplifier, as compared to a case where the additional inductance element is formed from a metal wire or a transmission line.

Further, the power amplifier of the present invention is preferably arranged such that the additional inductance element is formed from a bonding wire.

According to the arrangement, a decrease in saturated output power is suppressed because a bonding wire has a smaller parasitic resistance than that of a metal wire or a spiral coil. This makes it possible to easily increase a saturated output power of the power amplifier.

Further, the power amplifier of the present invention is preferably arranged such that an inductance of the additional inductance element is larger than the parasitic inductance.

Further, the power amplifier of the present invention is preferably arranged such that an inductance of the additional inductance element is 10 pH or larger.

The arrangement makes it possible to further increase an output power of the power amplifier.

The power amplifier of the present invention preferably further includes: a capacitor element between the emitter terminal and the ground, the capacitor element being connected in parallel with the additional inductance element, the capacitor element providing a resonance effect in cooperation with the additional inductance element, so that an inductance between the emitter terminal and the ground between which the capacitor element and the additional inductance element are provided is larger than an inductance between the ground and the emitter terminal which is grounded to the ground only via the additional inductance element.

According to the arrangement, the capacitor element connected in parallel with the additional inductance element is further provided between the emitter terminal and the ground. This increases an inductance, due to a resonance effect brought by the capacitor element and the additional inductance element, as compared to a case where the capacitor element is not provided. This makes it possible to further increase an output power of the power amplifier.

The power amplifier of the present invention preferably further includes a second bipolar transistor for amplifying a signal supplied thereto via a base terminal of the second bipolar transistor, and supplying to the base terminal of the first bipolar transistor the signal thus amplified.

The larger the inductance between the emitter terminal and the ground, the lower the gain of a grounded-emitter amplifier. According to the arrangement above, in contrast, the second bipolar transistor is further provided, and a signal amplified by the second bipolar transistor is amplified by the first bipolar transistor. The arrangement allows the second bipolar transistor to compensate a decrease in gain due to an increase in inductance between the emitter terminal of the first bipolar transistor and the ground.

An integrated circuit of the present invention is an integrated circuit in which the power amplifier is mounted on a semiconductor substrate.

A communication apparatus of the present invention includes the power amplifier as a transmission power amplifier.

The arrangement makes it possible to provide a highly efficient high-power communication apparatus.

The present invention can be also described as below.

The power amplifier of the present invention is a power amplifier for amplifying a signal supplied via an input terminal and outputting an amplified signal via an output terminal. The power amplifier includes (i) a first bipolar transistor having (a) a collector terminal connected with the output terminal so that a signal can be outputted via the output terminal and (b) a base terminal connected with the input terminal so that a signal can be supplied to the base terminal, and (ii) a first inductance of a predetermined value between an emitter terminal of the first bipolar transistor and an earth terminal.

A power amplifier integrated circuit of the present invention is a power amplifier integrated circuit including at least a metal wire and a bipolar transistor on a semiconductor substrate. A power amplifier of the power amplifier integrated circuit is a power amplifier for amplifying a signal supplied via an input terminal and outputting an amplified signal via an output terminal. The power amplifier includes (i) a first bipolar transistor having (a) a collector terminal connected with the output terminal so that a signal can be outputted via the output terminal and (b) a base terminal connected with the input terminal so that a signal can be supplied to the base terminal, and (ii) a first inductance of a predetermined value between an emitter terminal of the first bipolar transistor and an earth terminal which first inductance is formed from the metal wire.

The present invention makes it possible to provide a highly efficient high-power power amplifier, without increasing power consumption thereof. Accordingly, the present invention is applicable to communication apparatuses required to be low in distortion, high in output power, and high in efficiency, such as a portable phone and a wireless communication apparatus.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1. A power amplifier including a first bipolar transistor for amplifying a signal supplied thereto via a base terminal of the first bipolar transistor, so as to obtain an amplified signal, and outputting the amplified signal via a collector terminal of the first bipolar transistor, the power amplifier comprising:
an additional inductance element between an emitter terminal of the first bipolar transistor and a ground,
an inductance between the emitter terminal and the ground between which the additional inductance element is provided being larger than a parasitic inductance between the emitter terminal and the ground between which the additional inductance element is not provided.

2. The power amplifier as set forth in claim 1, wherein the additional inductance element is formed from a metal wire.

3. The power amplifier as set forth in claim 1, wherein the additional inductance element is formed from a transmission line.

4. The power amplifier as set forth in claim 1, wherein the additional inductance element is formed from a spiral coil.

5. The power amplifier as set forth in claim 1, wherein the additional inductance element is formed from a bonding wire.

6. The power amplifier as set forth in claim 1, wherein the additional inductance element has an inductance larger than the parasitic inductance.

7. The power amplifier as set forth in claim 6, wherein the inductance of the additional inductance element is 10 pH or larger.

8. The power amplifier as set forth in claim 1, further comprising:
a capacitor element between the emitter terminal and the ground, the capacitor element being connected in parallel with the additional inductance element,
the capacitor element providing a resonance effect in cooperation with the additional inductance element, so that an inductance between the emitter terminal and the ground between which the capacitor element and the additional inductance element are provided is larger than an inductance between the ground and the emitter terminal which is grounded to the ground only via the additional inductance element.

9. The power amplifier as set forth in claim 1, further comprising:
a second bipolar transistor for amplifying a signal supplied thereto via a base terminal of the second bipolar transistor, and supplying to the base terminal of the first bipolar transistor the signal thus amplified.

10. An integrated circuit comprising:
a semiconductor substrate; and
a power amplifier on the semiconductor substrate, the power amplifier including:
a first bipolar transistor for amplifying a first bipolar transistor for amplifying a signal supplied thereto via a base terminal of the first bipolar transistor, so as to obtain an amplified signal, and outputting the amplified signal via a collector terminal of the first bipolar transistor; and
an additional inductance element between an emitter terminal of the first bipolar transistor and a ground,
an inductance between the emitter terminal and the ground between which the additional inductance element is provided being larger than a parasitic inductance between the emitter terminal and the ground between which the additional inductance element is not provided.

11. A communication apparatus comprising:
a power amplifier as a transmission power amplifier, the power amplifier including:
a first bipolar transistor for amplifying a signal supplied thereto via a base terminal of the first bipolar transistor, so as to obtain an amplified signal, and outputting the amplified signal via a collector terminal of the first bipolar transistor; and
an additional inductance element between an emitter terminal of the first bipolar transistor and a ground,
an inductance between the emitter terminal and the ground between which the additional inductance element is provided being larger than a parasitic inductance between the emitter terminal and the ground between which the additional inductance element is not provided.
